(19) United States
(12) Patent Application Publication
(10) Pub. No.: US 2016/0163671 A1
(43) Pub. Date: Jun. 9, 2016

(54) INTEGRATED CIRCUIT PACKAGE WITH POWER PLATES

(71) Applicants: SHAILESH KUMAR, Ghaziabad (IN); Rishi Bhooshan, Ghaziabad (IN); Chee Seng Foong, Sg. Buloh (MY); Vikas Garg, Delhi (IN); Navas Khan Oratti Kalandar, Austin, TX (US); Chetan Verma, Noida (IN)

(72) Inventors: SHAILESH KUMAR, Ghaziabad (IN); Rishi Bhooshan, Ghaziabad (IN); Chee Seng Foong, Sg. Buloh (MY); Vikas Garg, Delhi (IN); Navas Khan Oratti Kalandar, Austin, TX (US); Chetan Verma, Noida (IN)

(73) Assignee: Freescale Semiconductor, Inc., Austin, TX (US)

(21) Appl. No.: 14/559,893

(22) Filed: Dec. 3, 2014

(51) Int. Cl. H01L 23/00; H01L 23/31; H01L 21/56; H01L 23/495

(52) U.S. Cl. CPC H01L 24/33; H01L 23/49517; H01L 24/17; H01L 23/3114; H01L 21/563; H01L 24/83; H01L 24/81; H01L 24/49; H01L 24/85; H01L 2224/335; H01L 2924/01029

(57) ABSTRACT

A surface-mounted integrated circuit package containing a semiconductor die has at least two conductive plates on its lower surface for contacting power and ground areas of a printed circuit board (PCB). The conductive plates are electrically connected to metal studs encapsulated within the package and which link the plates to the power and ground grids of the semiconductor die. Power and ground can thus be provided to the package with conductive patterns on the PCB that match with the plates. The resistance of the plates is low and hence the IR drop across the die is low. By supplying power directly to the package via the plates, the peripheral package pins that would otherwise have been allocated for power (and ground) are now freed up for signal assignment.

### BACKGROUND OF THE INVENTION

The present invention relates generally to integrated circuit packaging and, more particularly, to an integrated circuit package having power and ground plate connections.

Typically, a Quad Flat Package (QFP) has a number of pins (arranged around its periphery) that are shared between signal inputs and outputs (I/Os) and power and ground voltage connections. A QFP has many power and ground pins, for example, up to 20% of the pins and possibly even more, that are spaced around the periphery of the chip. As more logic gets integrated onto a single chip, there is a need for more signal pins. Thus, it would be advantageous to be able to allocate more of the pins around the periphery of the chip to signal I/Os.

### BRIEF DESCRIPTION OF THE DRAWINGS

The invention, together with objects and advantages thereof, may best be understood by reference to the following description of preferred embodiments together with the accompanying drawings in which:

FIG. 1 is a simplified plan view of an integrated circuit package in accordance with an embodiment of the present invention;

FIGS. 2A to 2H are cross-sectional side views of an integrated circuit package being assembled in accordance with a first example of the present invention; and

FIGS. 3A to 3I are cross-sectional side views of another integrated circuit package being assembled in accordance with a second example of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides an integrated circuit package for mounting on a printed circuit board (PCB). The package has an external face that includes first and second conductive plates, separated from each other by a gap, for contacting, respectively, power and ground areas of the PCB. The package includes a semiconductor die having a power terminal and a ground terminal, a first connector arrangement connected between the first conductive plate and the power terminal and a second connector arrangement connected between the second conductive plate and the ground terminal.

In another embodiment, the present invention provides a method of assembling an integrated circuit package for mounting on a PCB. The package includes a semiconductor die having at least one power terminal, at least one ground terminal, and a plurality of signal terminals. The method includes: attaching a first connector arrangement to the power terminal, attaching a second connector arrangement to the ground terminal, and attaching first and second conductive plates to the first and second connector arrangements. The conductive plates are for contact power and ground areas of the PCB.

By virtue of the invention, a conductive external structure, which may be copper, is used to feed power and ground to the package directly from the PCB on which the package is mounted.

In one embodiment, a third or any number of additional conductive plates are provided in instances where multiple voltages are required for the integrated circuit package. In such cases, all conductive plates are separated from each other by a gap and are therefore electrically isolated from one another. Similarly, corresponding third and additional connector arrangements are connected between the third and additional conductive plates to respective power terminals on the die.

Advantageously, the invention permits the freeing up of pins of a surface mount package for signal assignment by feeding power and ground connections directly from the PCB rather than using pins that would otherwise have been allocated for power and ground use. Also, advantageously, a package in accordance with the invention typically has a lower IR voltage drop (VDD+VSS) compared with a conventional package because power is fed through conductive plates rather than pins so resistance is reduced. The invention can also provide a pad-ring area saving and thereby an overall area saving of the package.

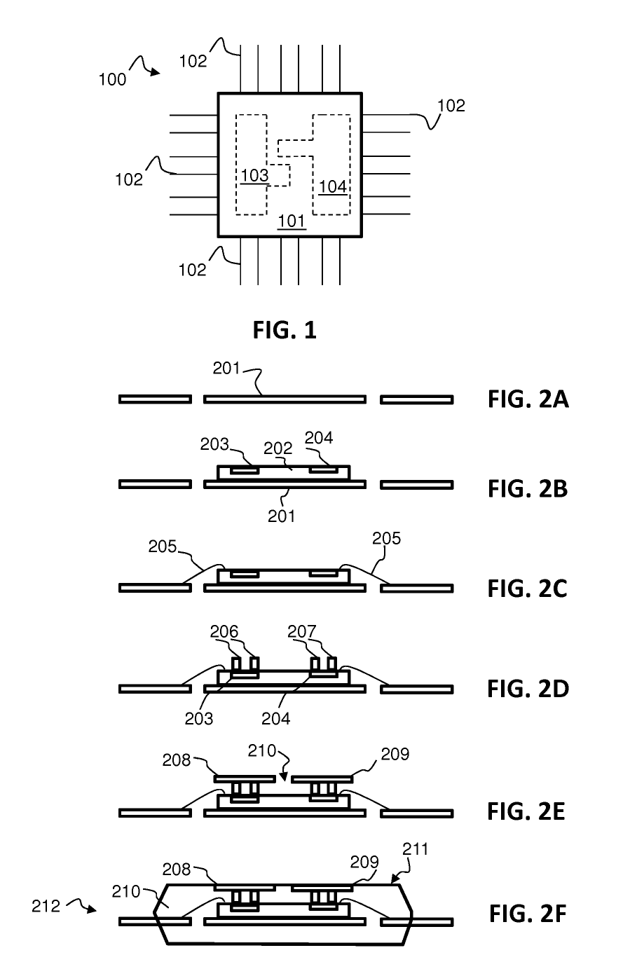

Referring now to FIG. 1, a plan view of an integrated circuit package in accordance with an embodiment of the present invention is shown. The package 100 has an upper surface 101 and is intended for mounting on a PCB. The package 100 has a plurality of peripheral pins 102 most or all of which are for signal input/output use. A lower surface of the package 100 contacts a PCB (not shown) and includes two conductive plates 103, 104. The first plate 103 comprises a power connection and is connected to an internal power grid (or trace) of the package 100 and contacts (e.g., can be soldered to) a matching pattern on the PCB. In this way, power, is supplied from the PCB to the package 100 via the first plate 103. The second plate 104 comprises a ground connection and is connected to an internal ground grid of the package 100 and contacts (e.g., can be soldered to) a matching pattern on the PCB. In this way, the ground connection of the PCB can be linked to the package 100 via the second plate 104. In one embodiment, the first and second plates 103, 104 are formed of bare copper. However, in other embodiments, the plates 103, 104 maybe plated, such as is known in the art for plating package leads.

In an alternative embodiment, instead of using power and ground grids, wire-bondable power and ground pads are used instead.

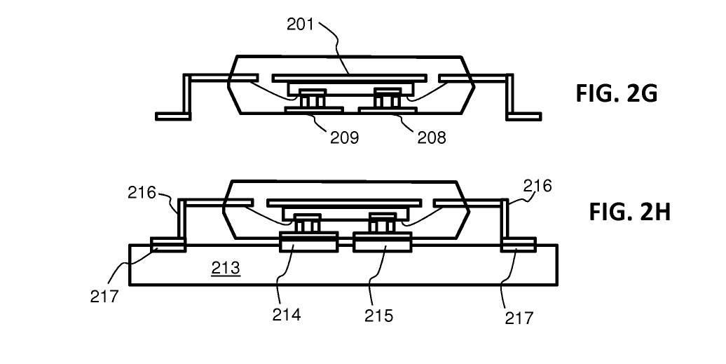

A first example of a method of assembling the integrated circuit package 100 will now be described with reference to FIGS. 2A to 2H.

A blank lead frame 201 is prepared (see FIG. 2A) in accordance with conventional techniques. The lead frame 201 can comprise any electrically conducting metal alloy and in one example is mainly copper-based. The lead frame 201 includes a die flag and a plurality of leads that surround the die flag.

FIG. 2B shows a semiconductor die 202 bonded or attached to the lead frame 201, and in particular to the die flag of the lead frame 201. The semiconductor die 202 can be any type of semiconductor, for example, silicon or gallium arsenide. The die 202 has at least one power terminal, at least one ground terminal, and a plurality of signal terminals. All of the terminals may be spaced around the periphery on an active surface of the die 202, or the signal terminals may be spaced around the periphery and the power and ground terminals located separately, away from the periphery (toward the center of the die). FIG. 2B shows a power terminal in the form of a power grid 203 and a ground terminal in the form of a ground grid 204 formed on the semiconductor die 202, using conventional techniques. In one example, power and ground grids are formed as part of the wafer fabrication process. In another example, the power and ground terminals are respectively, wire-bondable power and ground pads that are formed after wafer fabrication.

Next, as shown in FIG. 2C, bond wires 205 are used to electrically connect the die signal terminals to the leads of the lead frame 201. This wire bonding step is well known in the art.

FIG. 2D shows a first series of electrical connectors 206 bonded to the power grid 203 at the appropriate points on the grid, and a second series of connectors 207 bonded to the ground grid 204 at the appropriate points on this grid. In one embodiment, the electrical connectors 206, 207 are metal studs, which can be formed on the power and ground terminals using bond wires and a bonding machine, such as by stud bumping. The metal studs can be formed using copper or aluminium bond wire.

FIG. 2E shows a first plate 208 attached to the first series of connectors 206 and a second plate 209 attached to the second series of connectors 207. In this way, the first plate 208 forms a power connection for the package 100 and the second plate 209 forms a ground connection for the package 100. As previously mentioned, the first and second plates 208, 209 may comprise copper. The shape of the plates 208, 209 depends on the layout of the first and second series of connectors 206, 207. A gap 210 is left between the plates 208, 209 so that they are electrically isolated from one another. In one example, the plates 208, 209 are soldered to tips of the metal studs comprising the electrical connectors 206, 207 and reflowed. The plates 208, 209 can, in some embodiments, be fabricated using surface plated finishing techniques using nickel, OSP (Organic Solder Protection) or tin for example. In other embodiments, as an alternative to using copper, electrically conductive metal alloys can be employed instead.

In alternative embodiments, instead of metal studs, stud bumps, solder balls or copper pillars perform the function of the electrical connectors and are attached to the copper plates using known techniques. In one embodiment, the electrical connectors 206, 207 and plates 208, 209 are attached to the die 201 before the wire bonding step shown in FIG. 2C.

Next, the components shown in FIG. 2E are covered with a molding resin (or compound) 210, as shown in FIG. 2F, using a conventional molding process yet ensuring that the plates 208, 209 remain exposed on an outer surface 211 of the encapsulated package 212. Those parts of the outer surfaces of the plates 208, 209 that are not soldered to the electrical connectors 206, 207 will tend to stick to the moulding resin (compound) 210. Note that in the embodiment shown, the plates 208, 209 are flush with the outer surface 211 of the package 212.

As shown in FIG. 2G, the encapsulated package 212 is flipped (inverted), and the leads are trimmed and formed as is conventional.

In a subsequent step, FIG. 2H shows the encapsulated package mounted on a PCB 213 with the first copper plate 208 making contact with a power plane 214 of the PCB 213 and the second copper plate 209 making contact with a ground plane 215 of the PCB 213. Leads (or pins) 216, two of which are shown, are connected to signal pads 217 on the PCB 213. Usually, a soldered connection is made between the copper plates 208, 209 and the power and ground planes 214, 215. It can be seen that the power and ground terminals are located on a bottom surface of the package 212, while the signal pins 216 project from the sides of the package 212.

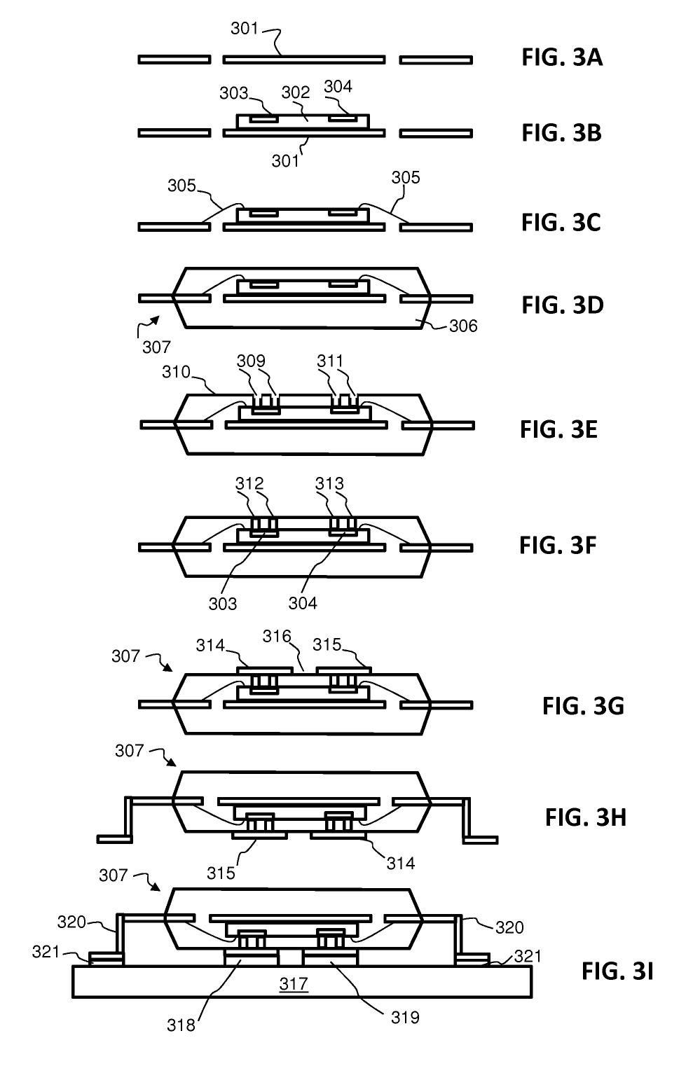

A second example of a method of assembling the integrated circuit package 100 of FIG. 1 will now be described with reference to FIGS. 3A to 3I.

FIG. 3A shows a blank lead frame 301 is provided. The lead frame 301 has a die flag and a plurality of leads that surround the die flag. The lead frame 301 can comprise any electrically conducting metal alloy and in one example is mainly copper-based.

FIG. 3B shows a semiconductor die 302 bonded or attached, for example using an epoxy adhesive, to the lead frame 301. The semiconductor die 302 can be any type of semiconductor, for example, silicon or gallium arsenide, and may comprise any type of integrated circuit such as a System on a Chip (SOC), a processor, or a micro-controller. In one embodiment, the die 302 has a plurality of signal bonding pads located on its top or active surface proximate the periphery. Further, a power grid 303 and a ground grid 304 are formed on the top, active surface of the semiconductor die 302 using conventional techniques.

FIG. 3C shows bond wires 305 electrically connecting the signal pads of the die 302 to the leads of the lead frame 301.

Next, the components shown in FIG. 3C are encapsulated in a molding resin (or compound) 306, as shown in FIG. 3D, using a conventional molding process to form an encapsulated package 307.

Next, as shown in FIG. 3E, a first series of holes 309 is drilled through the molding resin 306 from an external face 310 of the encapsulated package 307 through to the surface of the die 302, which is opposite the surface bonded to the lead frame 301. Similarly, a second series of holes 311 is drilled through the molding resin 306 from the external face 310 of the encapsulated package 307 through to the surface of the die 302, opposite the surface bonded to the lead frame 301. Drilling is done user a laser. In an alternative embodiment, instead of drilling holes, vias linking the external face 310 of the encapsulated package 307 with the upper surface of the die 302 and which are provided in the molding process, are subsequently opened. The first series of holes 309 (or vias) are aligned with the power grid 303 and the second series of holes 311 are aligned with the ground grid 304.

Next, as shown in FIG. 3F, the holes (or vias) 309, 311 are filled with solder such as by plugging the holes 309, 311 with solder balls 312 and 313. A first series of solder balls 312 make contact with the power grid 303 at the appropriate points on the grid, and a second series of solder balls 313 make contact with the ground grid 304 at the appropriate points on this grid.

Next, as shown in FIG. 3G, a first conductive plate 314 is connected to the first series of solder balls 312 and a second conductive plate 315 is connected to the second series of solder balls 313. In this way, the first plate 314 forms a power connection for the package 100 and the second plate 315 forms a ground connection for the package 100. The shape of each of the first and second plates 314, 315 depends on the layout of the first and second series of connectors 312, 313. A gap 316 is left between the two plates 314, 315 so that they are electrically isolated from one another. In one example, the plates 314, 315 are soldered to the first and second series of solder balls 312, 313 respectively and epoxy glued to those parts of the mold resin 306 between the solder balls. Note that, in contrast to the embodiment shown in FIG. 2F or 2G, in this embodiment the plates are lie on the outer surface of the molding resin instead of being flush therewith. The plates 314, 315 can, in some embodiments, be fabricated using surface plated finishing techniques using nickel, OSP or tin for example. In other embodiments, as an alternative to using copper, electrically conductive metal alloys can be employed instead.

The encapsulated package 307, which now includes the two conductive plates 314, 315 is flipped (inverted), as shown in FIG. 3H and the leads are trimmed and formed as is conventional.

The package 307 may be attached to a PCB, as shown in FIG. 3I. In FIG. 3I, the encapsulated package 307 is mounted on a PCB 317 with the first plate 314 making contact with a power plane 318 of the PCB and the second plate 315 making contact with a ground plane 319 of the PCB. Leads (or pins) 320, two of which are shown in FIG. 3I, are connected to signal pads 321 on the PCB 317. Soldering of the plates 314, 315 onto their respective PCB planes is employed in order to make permanent connections.

The semiconductor die described herein can be any semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described above.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. An integrated circuit package for mounting on a printed circuit board (PCB), comprising:
a lead frame having a die flag and a plurality of leads that surround the die flag, wherein each lead has a proximal end co-planar with the die flag and an opposite distal end;
a semiconductor die having an active side that has a power terminal, a ground terminal and a plurality of signal terminals located thereon, and an opposite back side mounted on the die flag of the lead frame;
a first connector arrangement connected to the power terminal;
a second connector arrangement connected to the ground terminal;
a first conductive plate connected to the first connector arrangement, wherein the first conductive plate is located at a first external face of the package;
a second conductive plate connected to the second connector arrangement, wherein the second conductive plate is located at a second external face of the package,
wherein the first conductive plate is for connection to a power area of the PCB and the second conductive plate is for connection to a ground area of the PCB; and
a molding compound that encapsulates the die and the first and second connector arrangements, wherein the distal end of each lead protrudes from the molding compound and is bent towards the active side of the semiconductor die for mounting the distal end of each lead to the PCB, wherein the first and second conductive plates are separated and electrically isolated from each other by the molding compound.

2. The integrated circuit package of claim 1, wherein each of the first and second connector arrangements comprises at least one metal stud.

3. The integrated circuit package of claim 1, wherein each of the first and second connector arrangements comprises at least one solder ball.

4. The integrated circuit package of claim 1, wherein the first and second conductive plates are copper.

5. The integrated circuit package of claim 1, wherein the first and second conductive plates are soldered to the first and second connector arrangements respectively.

6. (canceled)

7. The integrated circuit package of claim 1, wherein the die signal terminals are electrically connected to respective ones of the leads with bond wires.

8. (canceled)

9. A method for assembling an integrated circuit package for mounting on a printed circuit board (PCB), comprising the steps of:
forming a power terminal and a ground terminal on an active side of a semiconductor die;
attaching a first connector arrangement to the power terminal;
attaching a second connector arrangement to the ground terminal;
attaching a first conductive plate, for contacting a power area of the PCB, to the first connector arrangement;
attaching a second conductive plate, for contacting a ground area of the PCB, to the second connector arrangement;
providing a lead frame having a die flag and a plurality of leads that surround the die flag, wherein each lead has a proximal end co-planar with the die flag and an opposite distal end;
attaching a back side of the semiconductor die to the die flag;
encapsulating the semiconductor die and the first and second connector arrangements in a molding compound, wherein the first and second conductive plates are separated and electrically isolated from each other by the molding compound, and are exposed for contacting respective power and ground areas of the PCB, and wherein the distal ends of the leads protrude from the molding compound; and
bending the distal ends of the leads outside of the molding compound towards the active side of the semiconductor die for mounting the distal ends of the leads to the PCB.

10. The method of claim 9, wherein the first and second connector arrangements are electrically connected to the power and ground terminals respectively using bond wires.

11. (canceled)

12. The method of claim 9, further comprising attaching the first and second conductive plates to the first and second connector arrangements respectively using a soldering process.

13. (canceled)

14. The method of claim 9, further comprising encapsulating the semiconductor die after attaching the first and second conductive plates to the first and second connector arrangements respectively.

15. The method of claim 9, further comprising attaching the first and second conductive plates to the first and second connector arrangements respectively after encapsulating the semiconductor die.

16. The method of claim 15, further comprising forming holes in the molding compound through to the power and ground terminals, and plugging the formed holes with solder balls.

17. An integrated circuit package, comprising:
a lead frame including a die flag and a plurality of leads that surround the die flag, wherein each lead has a proximal end co-planar with the die flag and an opposite distal end;
a semiconductor die having a back side attached to the die flag and a front, active side having a power terminal, a ground terminal and a plurality of signal terminals, wherein the leads are bent towards the active side of the semiconductor die for mounting the distal ends of the leads to a PCB;
a first connector arrangement connected to the power terminal;
a second connector arrangement connected to the ground terminal;
a first conductive plate connected to the first connector arrangement, wherein the first conductive plate is located at a first external face of the package;
a second conductive plate connected to the second connector arrangement, wherein the second conductive plate is located at a second external face of the package;
bond wires electrically connecting the die signal terminals to respective ones of the leads; and
a mold compound that covers the die, bond wires, and first and second connector arrangements, wherein the first and second conductive plates are separated and electrically isolated from each other by the molding compound.

18. The integrated circuit package of claim 17, wherein the first and second connector arrangements comprise conductive metal studs.

19. The integrated circuit package of claim 17, wherein the first and second external faces are the same face.

20. The integrated circuit package of claim 19, wherein the first and second conductive plates are flush with the external face.
